(19) United States
(12) Patent Application Publication
(10) Pub. No.: US 2014/0035518 A1
(43) Pub. Date: Feb. 6, 2014

(54) DOCKING STATION FOR ELECTRONIC DEVICE

(71) Applicant: HON HAI PRECISION INDUSTRY CO., LTD., New Taipei (TW)

(72) Inventor: HUNG-CHANG CHEN, New Taipei (TW)

(73) Assignee: HON HAI PRECISION INDUSTRY CO., LTD., New Taipei (TW)

(21) Appl. No.: 13/670,458

(22) Filed: Nov. 7, 2012

(30) Foreign Application Priority Data
Aug. 1, 2012 (TW) 101127868

(51) Int. Cl. H02J 7/00; H05K 7/00

(52) U.S. Cl. 320/108; 361/679.01; 320/107

(57) ABSTRACT

A docking station for an electronic device capable of outputting video signals includes a first communicating unit capable of communicating with the electronic device to receive the video signals, a first input unit for receiving users' operation to generate operating signals, and a processor electrically connected with the first communicating unit and the first input unit. The processor generates signals for controlling the electronic device in response to the operating signals, and further displays the video signals on a larger screen.

### BACKGROUND

1. Technical Field

The present disclosure relates to docking stations, and particularly to a docking station for an electronic device.

2. Description of Related Art

Portable electronic devices, such as mobile phones, generally include a display for displaying information and an input unit having a plurality of keys for receiving users' operations. However, as portable electronic devices becomes smaller and thinner, the size of the display and the size of the keys is limited, which may result in poor viewing and inconvenience in operations.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the three views.

FIG. 1 is a perspective view of an electronic device assembly in accordance with a first embodiment.

FIG. 2 is a perspective view of an electronic device assembly in accordance with a second embodiment.

FIG. 3 is a block diagram of the electronic device assembly of FIGS. 1 and 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

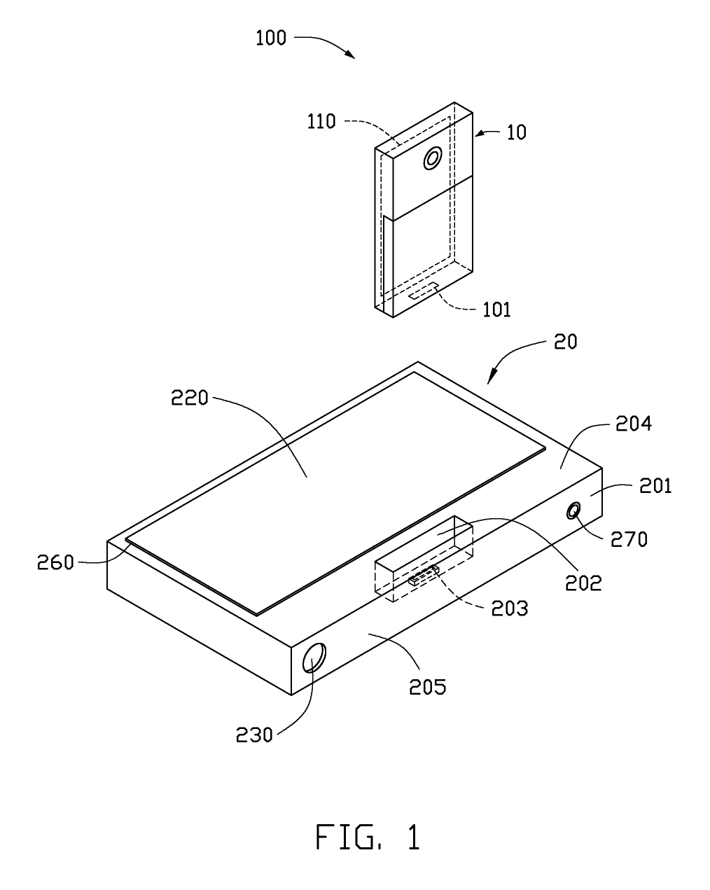

Referring to FIG. 1, an electronic device assembly 100 is shown. The electronic device assembly 100 includes an electronic device 10 and a docking station 20. The electronic device 10 is capable of generating video signals. The docking station 20 is capable of intercommunicating with the electronic device 10. The docking station 20 is adapted to receive the video signals from the electronic device 10 and displays the video signals on a larger screen. The docking station 20 is adapted to receive users' operations to generate signals for controlling the operation of the electronic device 10.

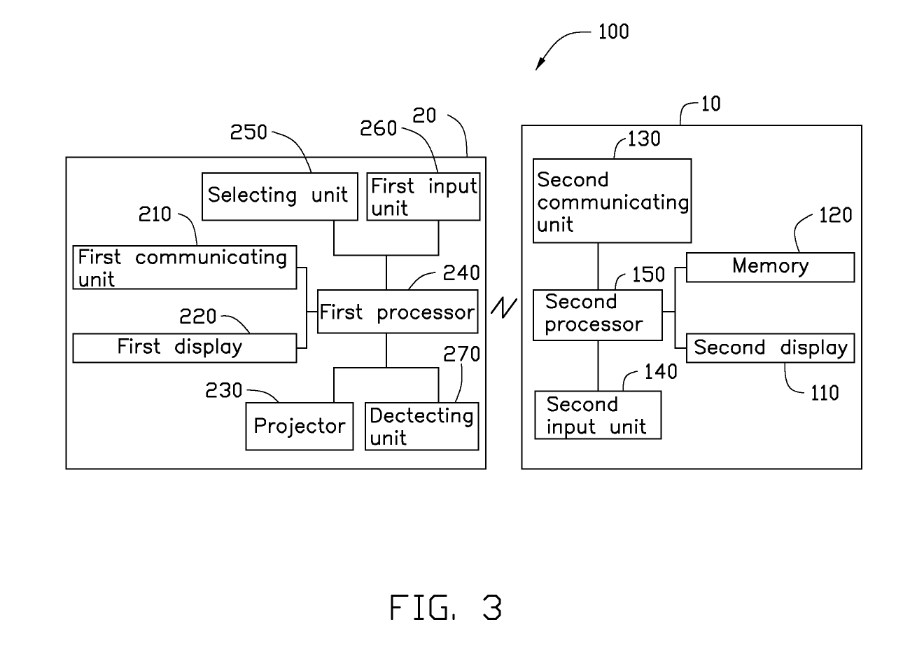

Referring also to FIG. 3, the docking station 20 includes a housing 201, a first communicating unit 210, a first display 220, a projector 230, a first processor 240, a selecting unit 250, and a first input unit 260. The first communicating unit 210, the first display 220, the projector 230, the selecting unit 250 and the first input unit 260 are all electrically connected to the first processor 240.

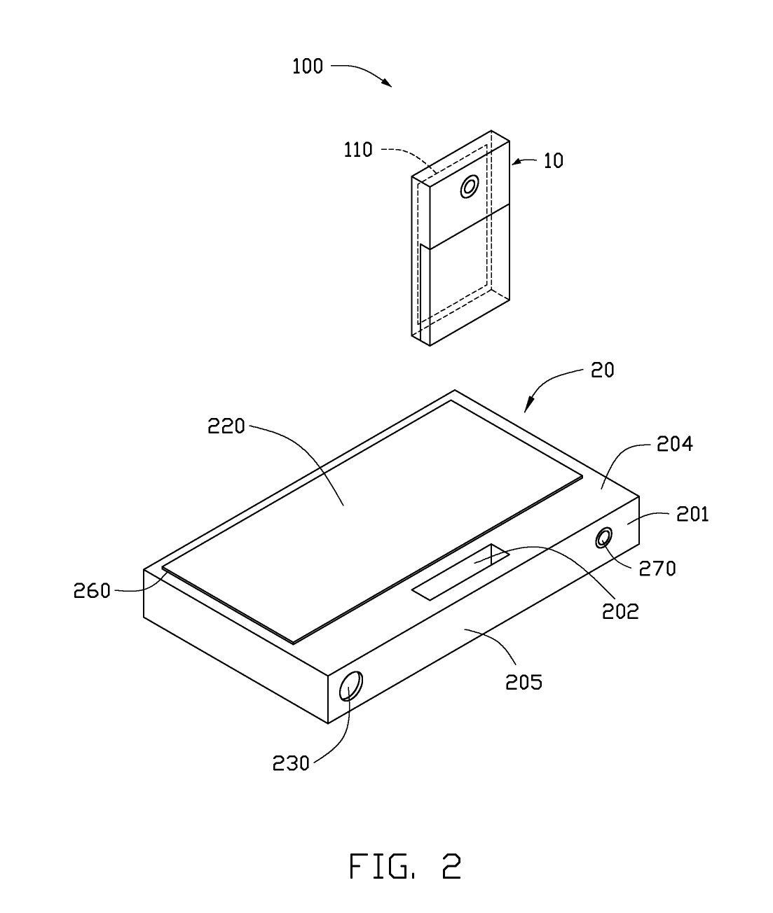

The housing 201 is substantially a hollow box in the embodiment. In other embodiments, the housing 201 may be ellipse, round and other shapes. The size of the housing 201 is greater than the size of the electronic device 10. The housing 201 includes a top surface 204 and a first sidewall 205 connecting with the top surface 204. The top surface 204 defines a receiving groove 202 for receiving the electronic device 10. The receiving groove 202 is adjacent to the first sidewall 205. In the embodiment, an interface 203 is secured to the bottom of the receiving groove 202. The interface 203 mates with a socket 101 of the electronic device 10, and is capable of insertion into the socket 101 to recharge the electronic device 10 when the electronic device 10 is received in the receiving groove 202. In other embodiments, referring to FIG. 2, the docking station 20 recharges the electronic device 10 in a non-contact manner, such as via induction coil.

The first communicating unit 210 is received in the housing 201. The first communicating unit 210 is adapted to communicate with the electronic device 10 for allowing the docking station 20 to intercommunicate with the electronic device 10. In the embodiment, the first communicating unit 210 communicates with the electronic device 10 in a wireless manner, such as by means of WI-F\BLUETOOTH\GSM\WCDMA or CDMA. In other embodiments, the first communicating unit 210 can communicate with the electronic device 10 through wires, such as USB cable.

The first display 220 is mounted on the top surface 204, and is adapted to display the video signals from the electronic device 10. The size of the first display 220 is larger than the size of the electronic device 10, thus, the video signals from the electronic device 10 are capable of being displayed by the first display 220 in an enlarged size.

The first input unit 260 is adapted to receive user's operations to generate signals. The first input unit 260 may be a keypad or a touch panel mounted on the housing 201. In the embodiment, the first input unit 260 is a touch panel covering the first display 220. Optimally, the first display 220 is a touch sensitive display, which is capable of displaying the video signals from the electronic device 10 and also receiving users' touch operations to generate signals.

The projector 230 is mounted on the first sidewall 205 of the housing 201. The projector 230 is adapted to project the video signals from the electronic device 10 onto a separate screen (not shown), to allow users to view an even larger image.

The selecting unit 250 is adapted to generate a signal when actuated. In the embodiment, the selecting unit 250 is a button mounted on the housing 201, and generates a switching signal when pressed.

The first processor 240 is adapted to select either the first display 220 or the projector 230 to play the video signals from the electronic device 10 in response to the switching signal. For example, when the first display 220 plays the video signals from the electronic device 10, the projector 230 will play the video signal from the electronic device 10 in response to the switching signal; when the projector 230 plays the video signals from the electronic device 10, the first display 220 will play the video signal from the electronic device 10 in response to the switching signal. As a result, users can choose either the first display 220 or the projector 230 to play the video signals from the electronic device 10. The first processor 240 is further adapted to generate signals in response to the operating signals and further transmit the signals to the electronic device 10 via the first communicating unit 210 to control the operation of the electronic device 10.

The docking station 20 further includes a detecting unit 270. The detecting unit 270 is mounted on the housing 201 (for example, the first sidewall 205) and is electrically connected to the first processor 240. The detecting unit 270 is adapted to monitor an area before the docking station 20 and generates a signal if the number of people within a predetermined proximity of the docking station 20 is greater than a predetermined value (such as 3). In the embodiment, the detecting unit 270 captures the monitored area to obtain an image, and detects the number of human faces in the captured image by Face Template Matching technology, and further generates a signal if the number of human faces is greater than the predetermined value. The first processor 240 further controls the projector 230 to play the video signals from the electronic device 10 in response to the signal. Thus, when the number of users is greater than the predetermined value, such as 3, the projector 230 is selected to automatically play the video signals from the electronic device 10 to allow more people to view the video.

The electronic device 10 in the embodiment is a portable communicating device, such as a mobile phone. The electronic device 10 includes a second display 110, a memory 120, a second communicating unit 130, a second input device 140, and a second processor 150. The size of the second display 110 is less than the size of the first display 220. The memory 120 is adapted to store video, images and other data. The second communicating unit 130 is adapted to communicate with the first communicating unit 210 to allow the electronic device 10 to intercommunicate with the docking station 20. The second inputting device 140 is adapted to receive users' operations and is capable of generating a first signal, a second signal and a third signal in response to users' operations. The first signal, the second signal and the third signal are different from each other. In the embodiment, the second inputting device 140 includes three different buttons for generating the first signal, the second signal, and the third signal respectively.

The second processor 150 obtains a video stored in the memory 120 and outputs the video signals. When the first signal is received, the second processor 150 displays the video signals in the second display 110. When the second signal is received, the second processor 150 transmits the video signals to the docking station 20 via the second communicating unit 130, to allow the video signals to be displayed by the first display 220 or the projector 230. When the third signal is received, the second processor 150 enables remote control signals and transmits any remote control signals to the docking station 20 for remotely controlling the docking station 20.

By virtue of the docking station 20, the video signals from the electronic device 10 are capable of being played by the first display 220 or the projector 230, to allow more people to view the enlarged video. Furthermore, because the size of the first input unit 260 is greater than the electronic device 10, a user can operate the first input unit 260 to control the electronic device 10 more easily.

Although information and advantages of the present embodiments have been set forth in the foregoing description, together with details of the structures and functions of the present embodiments, the disclosure is illustrative only; and that changes may be made in detail, especially in the matters of shape, size, and arrangement of parts within the principles of the present embodiments to the full extent indicated by the broad general meaning of the terms in which the appended claims are expressed.

What is claimed is:

1. A docking station for an electronic device capable of outputting video signals, comprising:
a first communicating unit capable of communicating with the electronic device to receive the video signals;
a first input unit for receiving users' operation to generate operating signals; and
a processor electrically connected with the first communicating unit and the first input unit;
wherein the processor generates signals for controlling operation of the electronic device in response to the operating signals, and further displays the video signals on a larger screen.

2. The docking station of claim 1, further comprising a first display for displaying the video signals from the electronic device; wherein the electronic device comprises a second display for displaying the video signals, the size of the first display is larger than the size of the second display.

3. The docking station of claim 2, wherein the first display is a touch sensitive display.

4. The docking station of claim 2, further comprising a projector for projecting the video signals from the electronic device onto a predetermined screen.

5. The docking station of claim 4, further comprising a selecting unit electrically connected to the first processor; wherein the selecting unit generates a switching signal when is actuated, the first processor selects one of the first display and the projector to play the video signals from the electronic device.

6. The docking station of claim 4, further comprising a detecting unit electrically connected to the first processor; wherein the detecting unit detects whether the number of people within a predetermined proximity of the docking station is greater than a predetermined value and generates a detecting signal if the number of people within a predetermined proximity of the docking station is greater than a predetermined value, the first processor controls the projector to project the video signals from the electronic device.

7. The docking station of claim 6, wherein the detecting unit captures an area before the docking station to obtain an image, and detects the number of human faces in the captured image, and further generates the detecting signal if the number of human faces is greater than the predetermined value.

8. The docking station of claim 1, further comprising a housing for receiving the first processor and the first communicating unit; wherein the housing defines a receiving groove for receiving the electronic device.

9. The docking station of claim 8, wherein an interface is secured to the bottom of the receiving groove, the interface mates with a socket of the electronic device and is capable of being inserted into the socket to recharge the electronic device.

10. The docking station of claim 8, wherein the docking station recharges the electronic device in a non-contact manner.
